(19) United States
(12) Patent Application Publication
(10) Pub. No.: US 2025/0210321 A1
(43) Pub. Date: Jun. 26, 2025

(54) SUBSTRATE PROCESSING APPARATUS

(71) Applicant: SEMES CO., LTD., Cheonan-si (KR)

(72) Inventors: Hyoung Kyu SON, Cheonan-si (KR); Eung Su KIM, Cheonan-si (KR); Hyun Jong SHIM, Cheonan-si (KR); Yoon Seok CHOI, Cheonan-si (KR); Gil Heyun CHOI, Cheonan-si (KR)

(73) Assignee: SEMES CO., LTD., Cheonan-si (KR)

(21) Appl. No.: 19/002,345

(22) Filed: Dec. 26, 2024

(30) Foreign Application Priority Data
Dec. 26, 2023 (KR) 10-2023-0191826

(51) Int. Cl. H01J 37/32

(52) U.S. Cl. CPC H01J 37/32669; H01J 2237/024; H01J 2237/334

(57) ABSTRACT

Disclosed is a substrate processing apparatus including chamber having defined therein a processing space for a processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller. The electromagnet unit includes a coil module including a plurality of unit coils and a magnetic inductor disposed between the plurality of unit coils. The substrate processing apparatus suppresses heat generation in the coil module and precisely controls a magnetic field.

### CROSS-REFERENCE TO THE RELATED APPLICATION

The present application claims priority to and the benefit of Korean Patent Application No. 10-2023-0191826, filed on Dec. 26, 2023, in the Korean Intellectual Property Office, the entire disclosure of which is incorporated herein by reference.

### BACKGROUND

### 1. Field

The present disclosure relates to a substrate processing apparatus configured to process a substrate using plasma.

### 2. Description of the Related Art

Substrate processing apparatuses using plasma are widely used to manufacture semiconductor devices. Plasma is generally used for a deposition process for forming a predetermined film on a substrate such as a semiconductor wafer, an etching process for forming a predetermined pattern on the film formed on the substrate, etc.

In some cases, such a plasma processing apparatus employs an electromagnet in order to control density distribution of plasma in a chamber. The electromagnet includes a coil, and is generally disposed outside the chamber accommodating a substrate. When current is applied to the coil, a magnetic field is formed in the chamber. The density distribution of the plasma generated in the chamber may be controlled by adjusting the intensity or distribution of the magnetic field.

For example, Patent Document 1 discloses technology in which a plurality of annular electromagnets is placed on a chamber in order to control a magnetic field in the chamber. The plurality of annular electromagnets has different radii and is disposed so as to be spaced apart from each other in a radial direction. However, this structure has a problem in that large mutual interference occurs between an inner coil and an outer coil due to a small gap therebetween, leading to increase in heat generation in the coils. The density distribution of plasma in the chamber may be controlled by adjusting the current flowing through the coils. However, this method has a problem in that it is difficult to perform precise control and it is difficult to independently control heat generation in the coils and the density distribution of plasma.

Therefore, there is a demand for technology capable of suppressing heat generation in coils and more precisely controlling a magnetic field.

### RELATED ART DOCUMENT

### Patent Document

(Patent Document 1) KR 10-2434088 B1

### SUMMARY

It is an object of the present disclosure to provide a substrate processing apparatus including an electromagnet, specifically, a substrate processing apparatus capable of suppressing heat generation in a coil included in an electromagnet and precisely controlling a magnetic field.

In accordance with the present disclosure, the above and other objects can be accomplished by the provision of a substrate processing apparatus including a chamber having defined therein a processing space for processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller, wherein the electromagnet unit includes a coil module including a plurality of unit coils and a magnetic inductor disposed between the plurality of unit coils.

In the embodiment of the present disclosure, the plurality of unit coils may be implemented as annular coils having different diameters and disposed concentrically with each other.

In addition, the magnetic inductor may include a plurality of unit magnetic inductors, and each of the plurality of unit magnetic inductors may be formed in an annular shape or a rod shape. Each of the plurality of unit magnetic inductors formed in an annular shape may be disposed between two adjacent ones of the plurality of unit coils.

In the embodiment of the present disclosure, the magnetic inductor may be formed in a structure in which a plurality of plate members is joined with each other.

In the embodiment of the present disclosure, the electromagnet unit may include a housing configured to accommodate the coil module and the magnetic inductor therein, and may further include a cooling fan configured to supply a cooling gas to an inner space in the housing. The magnetic inductor may have a slit hole formed therein to allow the cooling gas to pass therethrough. In addition, the magnetic inductor may have a refrigerant flow path formed therein to allow refrigerant supplied from a refrigerant source to flow therethrough.

The substrate processing apparatus according to the embodiment of the present disclosure may further include a lifting module configured to move the magnetic inductor up and down.

The magnetic inductor may include a plurality of unit magnetic inductors, and the lifting module may be configured to independently move each of the plurality of unit magnetic inductors up and down. Alternatively, the plurality of unit magnetic inductors may include at least a first group of unit magnetic inductors and a second group of unit magnetic inductors, and the lifting module may include a first motor configured to simultaneously move the first group of unit magnetic inductors up and down and a second motor configured to simultaneously move the second group of unit magnetic inductors up and down.

The substrate processing apparatus according to the embodiment of the present disclosure may further include a demagnetization module configured to demagnetize the magnetic inductor.

In the embodiment of the present disclosure, the demagnetization module may include an alternating current (AC) power supply and a first demagnetization coil configured to receive AC from the AC power supply to generate a magnetic field. In addition, the demagnetization module may include a second demagnetization coil configured to generate a magnetic field for demagnetization of the housing accommodating the magnetic inductor therein.

In the embodiment of the present disclosure, the first demagnetization coil may be disposed in the housing, and the second demagnetization coil may be disposed outside the housing.

In the embodiment of the present disclosure, the demagnetization module may further include a measurement unit configured to determine the degree of magnetization of the magnetic inductor. The controller may control the AC power supply to supply AC, determined based on the degree of magnetization of the magnetic inductor measured by the measurement unit, to the first demagnetization coil. In addition, the measurement unit may determine the degree of magnetization of the housing, and the controller may control the AC power supply to supply AC, determined based on the degree of magnetization of the housing measured by the measurement unit, to the second demagnetization coil.

In the embodiment of the present disclosure, the controller may sequentially perform a plasma-processing process of plasma-processing the substrate by controlling the plasma generation unit and the electromagnet unit and a demagnetization process of demagnetizing the magnetic inductor by controlling the AC power supply.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a cross-sectional view of a substrate processing apparatus according to an embodiment of the present disclosure;

FIGS. 2 and 3 are views for explaining the configuration of an electromagnet unit according to an embodiment of the present disclosure;

FIG. 4 is a view for explaining changes in the distribution and intensity of a magnetic field by a magnetic inductor;

FIGS. 5 and 6 are views for explaining a cooling structure of the magnetic inductor according to an embodiment of the present disclosure;

FIGS. 7 and 8 are views for explaining a cooling structure of the magnetic inductor according to another embodiment of the present disclosure;

FIGS. 9 and 10 are views for explaining embodiments of the electromagnet unit including a lifting module;

FIGS. 11 and 12 are views showing exemplary arrangement structures of the magnetic inductor;

FIG. 13 is a conceptual diagram of a demagnetization module for demagnetizing the magnetic inductor according to an embodiment of the present disclosure; and

FIG. 14 is a flowchart of a substrate processing method according to an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

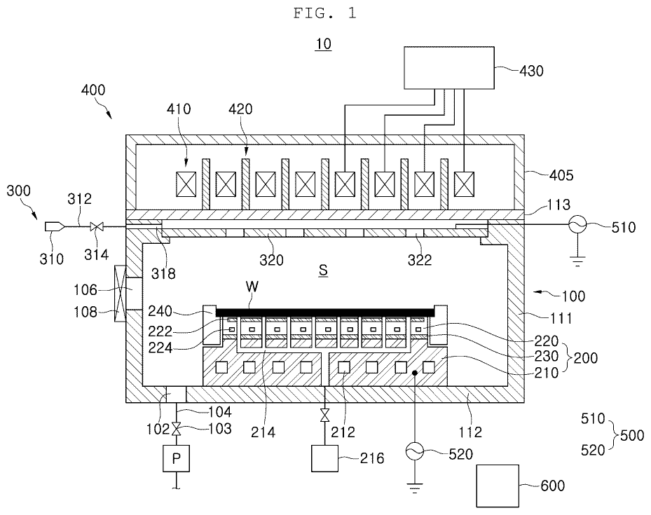

FIG. 1 is a cross-sectional view of a substrate processing apparatus according to an embodiment of the present disclosure.

Referring to FIG. 1, a substrate processing apparatus 10 according to an embodiment of the present disclosure includes a chamber 100, a substrate support unit 200, a gas supply unit 300, an electromagnet unit 400, a plasma generation unit 500, and a controller 600.

The chamber 100 has defined therein a processing space s in which a substrate-processing process is performed. The processing space s is defined in the chamber 100 by a chamber sidewall 111, a chamber bottom 112, and a chamber cover 113. The chamber 100 may be made of metal such as aluminum. The substrate-processing process may be a process of plasma-processing a substrate W. For example, the substrate-processing process may be a plasma etching process. The substrate-processing process may be performed in a reduced-pressure atmosphere. To this end, the chamber 100 may include an exhaust port 102 formed therein. The exhaust port 102 may be formed in the chamber bottom 112. A vacuum pump P is connected to the exhaust port 102 via an exhaust line 104 and an exhaust valve 103. The pressure in the processing space s in the chamber 100 may be adjusted to a predetermined pressure by operating the vacuum pump P and controlling the exhaust valve 103.

An opening 106 may be formed in the sidewall of the chamber 100. The opening 106 functions as a passage through which the substrate W is introduced into and removed from the chamber 100. An opening/closing door 108 is mounted in the opening 106. The opening/closing door 108 functions to open and close the opening 106 in the chamber 100. In the closed state, the opening/closing door 108 hermetically seals the processing space s in the chamber 100. In the open state, the opening/closing door 108 allows the substrate W to be transferred from a transfer space outside the chamber 100 to the processing space s or from the processing space s to the transfer space outside the chamber 100. The opening/closing door 108 may be a gate valve.

A substrate support unit 200 configured to support the substrate W is provided in the chamber 100. The substrate support unit 200 may include an electrostatic chuck 220 configured to attract and fix the substrate W thereto and a base plate 210 configured to support the electrostatic chuck 220. The electrostatic chuck 220 and the base plate 210 may be bonded to each other by means of a bonding layer 230, and the bonding layer 230 may be made of silicone or the like.

The electrostatic chuck 220 may be implemented as a dielectric plate made of alumina or the like, and may be provided therein with a chuck electrode 222 to generate electrostatic force. If voltage is applied to the chuck electrode 222 from a power supply (not shown), electrostatic force is generated, whereby the substrate W is attracted and fixed to the electrostatic chuck 220. The electrostatic chuck 220 may be provided with a heater 224 to adjust the temperature of the substrate W.

The base plate 210 may be located under the electrostatic chuck 220, and may be made of metal such as aluminum. The base plate 210 may have formed therein a refrigerant flow path 212 through which a cooling fluid flows, thereby functioning as a cooling device to cool the substrate W. The refrigerant flow path 212 may be provided as a circulation passage through which the cooling fluid circulates.

In addition, the substrate support unit 200 may have a heat transfer gas flow path 214 formed therein to provide a heat transfer gas to a lower surface of the substrate W from a heat transfer gas source 216. The heat transfer gas may facilitate heat transfer between the substrate W and the base plate 210, thereby promoting cooling of the substrate W. Helium (He) may be used as the heat transfer gas.

The substrate support unit 200 may include a ring member 240 to surround the periphery of the electrostatic chuck 220. The ring member 240 may have a stepped portion formed on an upper side thereof to support the outer circumferential surface of the substrate W. The ring member 240 may be made of a ceramic material, and may be a focus ring.

The gas supply unit 300 supplies gas required to process the substrate W to the chamber 100. The gas supply unit 300 may include a gas source 310, a gas supply line 312, a gas supply valve 314, a gas spray nozzle 318, and a showerhead 320. The gas supply line 312 connects the gas source 310 to the gas spray nozzle 318. A gas supply valve 314 is mounted on the gas supply line 312 in order to open and close the passage thereof or to regulate the flow rate of fluid flowing through the passage. Gas sprayed from the gas spray nozzle 318 is supplied to a space between the chamber cover 113 and the showerhead 320, and is then supplied to the processing space s through gas spray holes 322 formed in the showerhead 320.

Although one gas source 310, one gas supply line 312, and one gas supply valve 314 are illustrated in FIG. 1, the gas source 310 of the present disclosure may include a plurality of gas sources to supply a plurality of gases to the chamber 100 and a plurality of gas supply valves to independently control the supply of the respective gases. The plurality of gases may include a process gas used for a process of processing the substrate W, e.g., an etching gas, and may include an inert purge gas.

The plasma generation unit 500 may include high-frequency power supplies 510 and 520 to supply high-frequency power, thereby generating plasma in the processing space s. The high-frequency power supplies 510 and 520 may provide high-frequency power in the range of several hundred kHz to several hundred MHZ.

The high-frequency power supply 510 may supply high-frequency power to an upper electrode, and the showerhead 320 may function as the upper electrode. The high-frequency power supply 520 may supply high-frequency power to a lower electrode, and the substrate support unit 200 may function as the lower electrode. Although the high-frequency power supplies 510 and 520 are illustrated in FIG. 1 being connected to the upper electrode and the lower electrode, respectively, it should be understood that this configuration is merely exemplary. In order to generate plasma in the processing space s, the upper electrode may be grounded, and high-frequency power may be applied only to the lower electrode from the lower power supply 520. Alternatively, high-frequency power may be applied to the upper electrode from the upper power supply 510, and the lower electrode may be grounded. Alternatively, high-frequency power may be applied both to the upper electrode and to the lower electrode. A plurality of high-frequency power supplies having different frequencies may be used as the lower power supply 520.

The high-frequency power supplies 510 and 520 may apply power in a continuous mode or a pulse mode.

The electromagnet unit 400 is disposed on the chamber 100, and is configured to generate a magnetic field in the processing space s. The electromagnet unit 400 includes a housing 405, a coil module 410, a magnetic inductor 420, and an electromagnet excitation power supply 430. When current is supplied to the coil module 410 from the electromagnet excitation power supply 430, a magnetic field is generated in the processing space s as the current flows through the coil. Because the magnetic field generated in the processing space s is varied by controlling the current supplied to the coil module, it is possible to control the density distribution of plasma generated in the processing space s. The electromagnet excitation power supply 430 may be a direct current (DC) power supply that supplies direct current to the coil module.

The controller 600 may control overall operation of the substrate processing apparatus 10. For example, the controller 600 may control operation of the gas supply unit 300, the plasma generation unit 500, and the electromagnet unit 400 so that plasma processing is performed on the substrate W. For example, the controller 600 may control the gas supply unit 300 to supply a predetermined etching gas to the processing space s, and may control the high-frequency power supplies 510 and 520 to generate plasma in the processing space s, thereby etching the substrate W. In this case, the controller 600 may control the electromagnet unit 400 to generate a magnetic field in the processing space s, thereby appropriately controlling the density distribution of the plasma. Accordingly, it is possible to achieve uniform etching over the entire area of the substrate W.

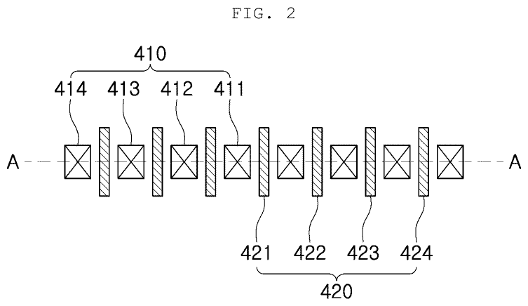

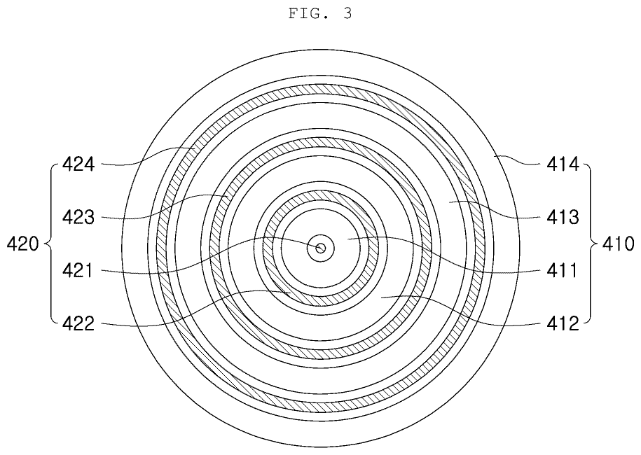

FIGS. 2 and 3 are views for explaining the configuration of the electromagnet unit 400 according to an embodiment of the present disclosure. FIG. 2 is a cross-sectional view for explaining the arrangement structure of the coil module 410 and the magnetic inductor 420, and FIG. 3 is a top view of the cross-section taken along line A-A in FIG. 2.

Referring to FIGS. 2 and 3, the electromagnet unit 400 according to an embodiment of the present disclosure includes the coil module 410. The coil module 410 may include a plurality of unit coils 411, 412, 413, and 414. The unit coils 411, 412, 413, and 414 may be annular coils having different diameters, and may be disposed concentrically with each other, as shown in FIG. 3. For example, the coil module 410 may include a first coil 411 formed in an annular shape, a second coil 412 formed in an annular shape having a larger diameter than the first coil 411 and disposed concentrically with the first coil 411, a third coil 413 formed in an annular shape having a larger diameter than the second coil 412 and disposed concentrically with the second coil 412, and a fourth coil 414 formed in an annular shape having a larger diameter than the third coil 413 and disposed concentrically with the third coil 413. Although the coil module 410 is illustrated in FIGS. 2 and 3 as including four unit coils, the disclosure is not limited thereto. The coil module 410 may include more than or less than four unit coils.

Each of the unit coils 411, 412, 413, and 414 may be provided in a form in which a coil is wound around a bobbin. The bobbin may be formed in an annular shape, and may be made of a material allowing a magnetic field to pass therethrough. For example, the bobbin may be made of aluminum.

The magnetic inductor 420 may be disposed between the unit coils 411, 412, 413, and 414. The magnetic inductor 420 may include a plurality of unit magnetic inductors 421, 422, 423, and 424. The unit magnetic inductors 421, 422, 423, and 424 may be formed in annular shapes having different diameters or rod shapes. As shown in FIG. 3, the unit magnetic inductors 421, 422, 423, and 424 may be disposed concentrically with each other. For example, the magnetic inductor 420 may include a first magnetic inductor 421 formed in a rod shape and spaced apart from the inner wall of the first coil 411 having an annular shape, a second magnetic inductor 422 formed in an annular shape and disposed between the first coil 411 and the second coil 421 while being concentric with the first magnetic inductor 421, a third magnetic inductor 423 formed in an annular shape and disposed between the second coil 412 and the third coil 413 while being concentric with the second magnetic inductor 422, and a fourth magnetic inductor 424 formed in an annular shape and disposed between the third coil 413 and the fourth coil 414 while being concentric with the third magnetic inductor 423. Although the magnetic inductor 420 is illustrated in FIGS. 2 and 3 as including four unit magnetic inductors, the disclosure is not limited thereto. The magnetic inductor 420 may include more than or less than four unit magnetic inductors depending on the configuration of the coil module 410. That is, the magnetic inductor 420 may include unit magnetic inductors, the number of which is identical to the number of unit coils constituting the coil module 410.

The magnetic inductor 420 may be made of a material having high magnetic permeability. For example, the magnetic inductor 420 may be made of a material containing at least one element of silicon (Si), cobalt (Co), or iron (Fe). The magnetic inductor 420 may be made of a material having magnetic permeability of 10 to 10,000 H/m. Each of the unit magnetic inductors 421, 422, 423, and 424 having an annular shape may be manufactured in a structure in which a plurality of plate members is joined with each other.

As shown in FIG. 2, the magnetic inductor 420 may be formed to have a height sufficient to isolate the unit coils 411, 412, 413, and 414 from each other.

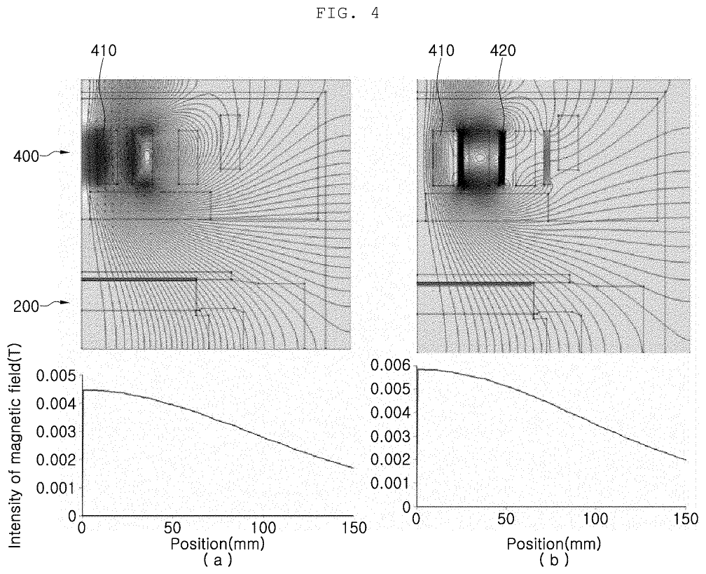

FIG. 4 is a view for explaining changes in the distribution and intensity of the magnetic field by the magnetic inductor 420. FIG. 4(a) shows a case in which the magnetic inductor 420 is not provided, and FIG. 4(b) shows a case in which the magnetic inductor 420 is disposed as shown in FIGS. 2 and 3. As can be seen from FIG. 4, when the magnetic inductor 420 is disposed, a magnetic field is induced in the magnetic inductor 420, and thus the number of lines of magnetic force (magnetic flux) passing through the coil module 410 is reduced compared to when the magnetic inductor 420 is not provided. Accordingly, heat generation in the coil module 410 may be minimized. In addition, referring to the graphs in FIG. 4 indicating a change in the intensity of the magnetic field, when the magnetic inductor 420 is disposed, the intensity of the magnetic field increases compared to when the magnetic inductor 420 is not provided. Accordingly, it is possible to more precisely control the density distribution of plasma.

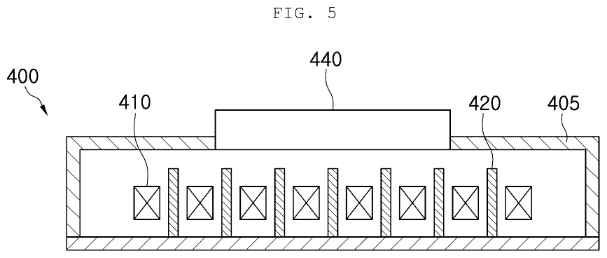

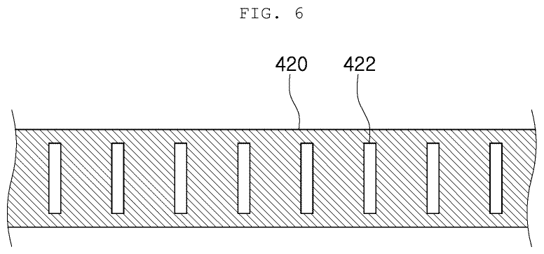

FIGS. 5 and 6 are views for explaining a cooling structure of the magnetic inductor 420 according to an embodiment of the present disclosure. FIG. 5 is a cross-sectional view of the electromagnet unit 400, and FIG. 6 is a plan view of the unit magnetic inductor 420.

As shown in FIG. 5, a cooling fan 440 may be mounted on the upper surface of the housing 405 of the electromagnet unit 400. The cooling fan 440 may supply a cooling gas such as air to the inner space in the housing 405, and the cooling gas may cool the magnetic inductor 420 while circulating in the housing 405. As shown in FIG. 6, a slit hole 422 may be formed in the magnetic inductor 420 in order to ensure smooth circulation of the cooling gas. The cooling gas may circulate in the inner space in the housing 405 while passing through the magnetic inductor 420 due to the slit hole 422.

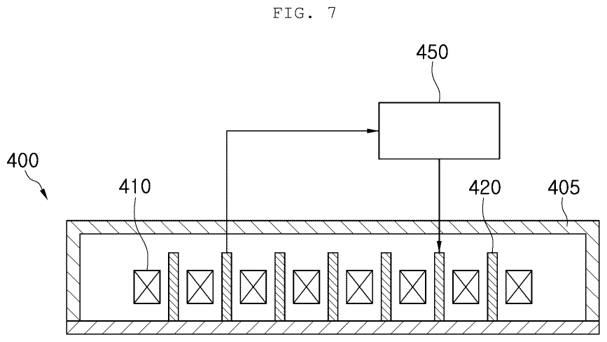

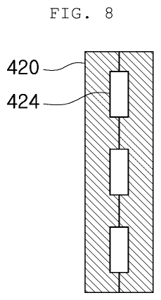

FIGS. 7 and 8 are views for explaining a cooling structure of the magnetic inductor according to another embodiment of the present disclosure. FIG. 7 is a cross-sectional view of the electromagnet unit 400, and FIG. 8 is an enlarged cross-sectional view of the unit magnetic inductor 420.

Referring to FIGS. 7 and 8, a refrigerant flow path 424 may be formed in the magnetic inductor 420. The magnetic inductor 420 may be manufactured in a structure in which a plurality of plate members is joined with each other, and the refrigerant flow path 424 may be formed by a groove formed in each plate member. Refrigerant supplied from a refrigerant source 450 may cool the magnetic inductor 420 while flowing through the refrigerant flow path 424. The refrigerant having passed through the refrigerant flow path 424 may return back to the refrigerant source 450. Although FIG. 7 illustrates a structure in which the refrigerant is supplied to one unit magnetic inductor 420, the refrigerant may be supplied to all the unit magnetic inductors 420.

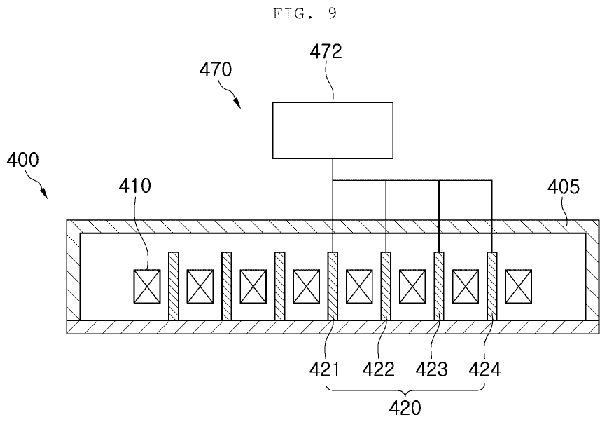

The substrate processing apparatus according to the embodiment of the present disclosure may include a lifting module 470 capable of moving the magnetic inductor 420 up and down. As shown in FIG. 9, the lifting module 470 may include a motor 472. The motor 472 is connected to the magnetic inductor 420 in order to independently move each of the unit magnetic inductors 421, 422, 423, and 424 up and down.

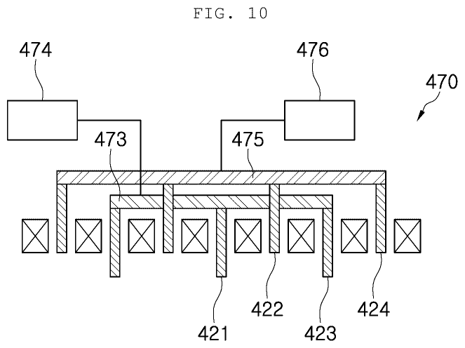

Alternatively, the magnetic inductor 420 may be divided into multiple groups, and each of the groups may be independently moved up and down. For example, as shown in FIG. 10, the first magnetic inductor 421 and the third magnetic inductor 423 are coupled to a first upper plate 473 so as to be moved simultaneously up and down by a first motor 474. The first motor 474 moves the first upper plate 473 up and down, thereby allowing the first magnetic inductor 421 and the third magnetic inductor 423 coupled to the first upper plate 473 to move up and down simultaneously. In addition, the second magnetic inductor 422 and the fourth magnetic inductor 424 are coupled to a second upper plate 475 so as to be moved simultaneously up and down by a second motor 476. The second motor 476 moves the second upper plate 475 up and down, thereby allowing the second magnetic inductor 422 and the fourth magnetic inductor 424 coupled to the second upper plate 475 to move up and down simultaneously.

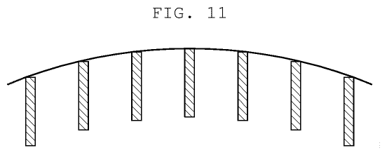

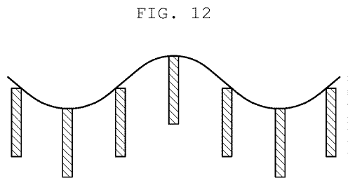

Because the distribution of the magnetic field changes when the magnetic inductor 420 is moved up and down, it is possible to more precisely control the density distribution of plasma in the processing space s than when only the current supplied to the coil module 410 is controlled. FIGS. 11 and 12 show exemplary arrangement structures of the magnetic inductor 420. In FIGS. 11 and 12, illustration of the coil module 410 is omitted. FIG. 11 shows a concave arrangement structure in which the heights of the magnetic inductors are gradually increased in a direction from the periphery of the housing toward the center of the housing. FIG. 12 shows a wave-shaped arrangement structure in which the heights of the magnetic inductors are reduced and then increased in a direction from the periphery of the housing toward the center of the housing.

If the magnetic inductor 420 is maintained in a magnetized state, it may affect the plasma. Therefore, it is necessary to periodically demagnetize the magnetic inductor 420. In an embodiment, the magnetic inductor 420 may be demagnetized whenever one substrate W is completely processed.

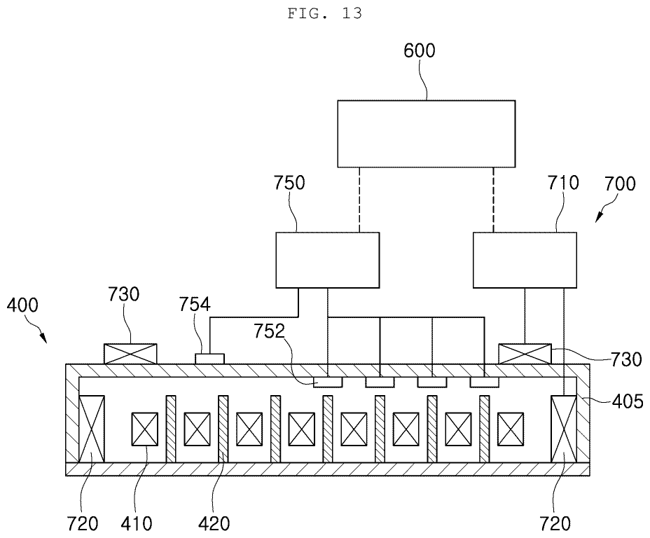

FIG. 13 is a conceptual diagram of a demagnetization module for demagnetizing the magnetic inductor 420 according to an embodiment of the present disclosure. Referring to FIG. 13, the demagnetization module 700 may include an alternating current (AC) power supply 710, a first demagnetization coil 720, a second demagnetization coil 730, and a measurement unit 750. The AC power supply 710 supplies AC to the first demagnetization coil 720 and/or the second demagnetization coil 730 to demagnetize the magnetic inductor 420. The AC power supply 710 is connected to the controller 600 and supplies adequate AC in accordance with the degree of magnetization of the magnetic inductor 420 measured by the measurement unit 750. The AC power supply 710 may be controlled to supply smaller AC as the demagnetization of the magnetic inductor 420 progresses.

The first demagnetization coil 720 is disposed in the housing 405 and demagnetizes the magnetic inductor 420. The first demagnetization coil 720 may be provided as an annular coil surrounding the magnetic inductor 420. The first demagnetization coil 720 may receive AC from the AC power supply 710 to form a magnetic field capable of demagnetizing the magnetic inductor. A first sensor 752 capable of measuring the degree of magnetization of the magnetic inductor 420 may be disposed in the housing 405. The first sensor 752 may be disposed adjacent to the plurality of unit magnetic inductors 421, 422, 423, and 424 to measure the degree of magnetization of each of the unit magnetic inductors 421, 422, 423, and 424. A result of the measurement by the first sensor 752 may be transmitted to the measurement unit 750, and the controller 600 may control the AC power supply 710 based on the measurement result.

The second demagnetization coil 730 is disposed on the housing 405 to demagnetize the housing 405. The housing 405 is made of a material that hardly transmits a magnetic field, and thus may be magnetized by the magnetic field originating from the coil module 410. Therefore, it is necessary to periodically demagnetize the housing 405. The second demagnetization coil 730 may receive AC from the AC power supply 710 to form a magnetic field capable of demagnetizing the housing. A second sensor 754 capable of measuring the degree of magnetization of the housing 405 may be disposed outside the housing 405. A result of the measurement by the second sensor 754 may be transmitted to the measurement unit 750, and the controller 600 may control the AC power supply 710 based on the measurement result.

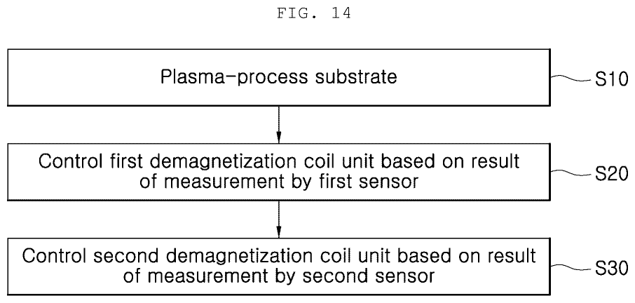

FIG. 14 is a flowchart of a substrate processing method according to an embodiment of the present disclosure. Specifically, FIG. 14 is a diagram for explaining a demagnetization method. Step S10 is a step of plasma-processing the substrate W. First, the substrate W is introduced into the chamber 100, and is placed on the substrate support unit 200. Subsequently, the controller 600 controls the gas supply unit 300 and the plasma generation unit 500 to generate plasma in the processing space s. At this time, in order to precisely control the density distribution of the plasma, the controller 600 plasma-processes the substrate W while controlling the electromagnet unit 400. In detail, current is supplied to the coil module 410 to generate a magnetic field, and the density distribution of the plasma is controlled by the generated magnetic field. Upward/downward movement of the magnetic inductor 420 may be controlled in order to more precisely control the density distribution of the plasma. The magnetic inductor 420 also functions to prevent overheating of the coil module 410. The cooling fan 440 or the refrigerant source 450 may be used in order to cool the magnetic inductor 420.

When plasma-processing is completely performed on the substrate W, step S20 of demagnetizing the magnetic inductor 420 may be performed. Specifically, the degree of magnetization of the magnetic inductor 420 may be determined based on a result of measurement by the first sensor 752, and adequate AC may be supplied to the first demagnetization coil 720 from the AC power supply 710 based on the result. As the demagnetization progresses, the degree of magnetization of the magnetic inductor 420 gradually decreases, and thus the AC supplied from the AC power supply 710 may be controlled to decrease over time. The AC over time may be determined based on the measurement result fed back from the first sensor 752.

Step S30 of demagnetizing the housing 405 may be performed before, after, or simultaneously with step S20. Specifically, the degree of magnetization of the housing 405 may be determined based on a result of measurement by the second sensor 754, and adequate AC may be supplied to the second demagnetization coil 730 from the AC power supply 710 based on the result. As the demagnetization progresses, the degree of magnetization of the housing 405 gradually decreases, and thus the AC supplied from the AC power supply 710 may be controlled to decrease over time. The AC over time may be determined based on the measurement result fed back from the second sensor 754.

As is apparent from the above description, according to the embodiment of the present disclosure, since a magnetic inductor is disposed between electromagnets, it is possible to suppress heat generation in a coil.

In addition, according to the embodiment of the present disclosure, since the magnetic inductor is configured to be adjustable in position, it is possible to precisely control a magnetic field.

Although the embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A substrate processing apparatus comprising:
a chamber having defined therein a processing space for processing of a substrate;
a substrate support unit disposed in the chamber;
a gas supply unit configured to supply gas to an interior of the chamber;
a plasma generation unit comprising a high-frequency power supply configured to generate plasma in the processing space;
an electromagnet unit configured to generate a magnetic field in the processing space; and
a controller,
wherein the electromagnet unit comprises:
a coil module comprising a plurality of unit coils; and
a magnetic inductor disposed between the plurality of unit coils.

2. The substrate processing apparatus as claimed in claim 1,
wherein the plurality of unit coils is implemented as annular coils having different diameters and disposed concentrically with each other.

3. The substrate processing apparatus as claimed in claim 2,
wherein the magnetic inductor comprises a plurality of unit magnetic inductors, and
wherein each of the plurality of unit magnetic inductors is formed in an annular shape or a rod shape.

4. The substrate processing apparatus as claimed in claim 3,
wherein each of the plurality of unit magnetic inductors formed in an annular shape is disposed between two adjacent ones of the plurality of unit coils.

5. The substrate processing apparatus as claimed in claim 1,
wherein the magnetic inductor is formed in a structure in which a plurality of plate members is joined with each other.

6. The substrate processing apparatus as claimed in claim 1,
wherein the electromagnet unit comprises a housing configured to accommodate the coil module and the magnetic inductor therein, and further comprises a cooling fan configured to supply a cooling gas to an inner space in the housing.

7. The substrate processing apparatus as claimed in claim 6,
wherein the magnetic inductor has a slit hole formed therein to allow the cooling gas to pass therethrough.

8. The substrate processing apparatus as claimed in claim 1,
wherein the magnetic inductor has a refrigerant flow path formed therein to allow refrigerant supplied from a refrigerant source to flow therethrough.

9. The substrate processing apparatus as claimed in claim 1, further comprising a lifting module configured to move the magnetic inductor up and down.

10. The substrate processing apparatus as claimed in claim 9,
wherein the magnetic inductor comprises a plurality of unit magnetic inductors, and
wherein the lifting module is configured to independently move each of the plurality of unit magnetic inductors up and down.

11. The substrate processing apparatus as claimed in claim 9,
wherein the magnetic inductor comprises a plurality of unit magnetic inductors,
wherein the plurality of unit magnetic inductors comprises at least a first group of unit magnetic inductors and a second group of unit magnetic inductors, and
wherein the lifting module comprises:
a first motor configured to simultaneously move the first group of unit magnetic inductors up and down; and
a second motor configured to simultaneously move the second group of unit magnetic inductors up and down.

12. A substrate processing apparatus comprising:
a chamber having defined therein a processing space for processing of a substrate;
a substrate support unit disposed in the chamber;
a gas supply unit configured to supply gas to an interior of the chamber;
a plasma generation unit comprising a high-frequency power supply configured to generate plasma in the processing space;
an electromagnet unit comprising a coil module configured to generate a magnetic field in the processing space and a magnetic inductor disposed adjacent to the coil module; and
a demagnetization module configured to demagnetize the magnetic inductor.

13. The substrate processing apparatus as claimed in claim 12,
wherein the coil module comprises a plurality of unit coils, and
wherein the magnetic inductor comprises a plurality of unit magnetic inductors, each being disposed between two adjacent ones of the plurality of unit coils.

14. The substrate processing apparatus as claimed in claim 13,
wherein the demagnetization module comprises:
an alternating current (AC) power supply; and
a first demagnetization coil configured to receive AC from the AC power supply to generate a magnetic field.

15. The substrate processing apparatus as claimed in claim 14,
wherein the demagnetization module comprises a second demagnetization coil configured to generate a magnetic field for demagnetization of a housing accommodating the magnetic inductor therein.

16. The substrate processing apparatus as claimed in claim 15,
wherein the first demagnetization coil is disposed in the housing, and the second demagnetization coil is disposed outside the housing.

17. The substrate processing apparatus as claimed in claim 16,
wherein the demagnetization module further comprises a measurement unit configured to determine a degree of magnetization of the magnetic inductor.

18. The substrate processing apparatus as claimed in claim 17, further comprising:
a controller configured to control the AC power supply to supply AC to the first demagnetization coil,
wherein the AC is determined based on the degree of magnetization of the magnetic inductor measured by the measurement unit.

19. The substrate processing apparatus as claimed in claim 17, further comprising:
a controller,
wherein the measurement unit determines a degree of magnetization of the housing,
wherein the controller controls the AC power supply to supply AC to the second demagnetization coil, and
wherein the AC is determined based on the degree of magnetization of the housing measured by the measurement unit.

20. A substrate processing apparatus comprising:
a chamber having defined therein a processing space for processing of a substrate;
a substrate support unit disposed in the chamber;
a gas supply unit configured to supply gas to an interior of the chamber;
a plasma generation unit comprising a high-frequency power supply configured to generate plasma in the processing space;
an electromagnet unit disposed in a housing disposed on the chamber, the electromagnet unit comprising a coil module configured to generate a magnetic field in the processing space and a magnetic inductor disposed adjacent to the coil module;
a lifting module configured to move the magnetic inductor up and down;
a demagnetization module configured to demagnetize the magnetic inductor,
wherein the coil module comprises a plurality of unit coils implemented as annular coils having different diameters and disposed concentrically with each other,
wherein the magnetic inductor comprises a plurality of unit magnetic inductors, each being formed in an annular shape and disposed between two adjacent ones of the plurality of unit coils, and
wherein the demagnetization module comprises:
an AC power supply;
a first demagnetization coil configured to receive AC from the AC power supply to generate a magnetic field and thus to demagnetize the magnetic inductor; and
a second demagnetization coil configured to receive AC from the AC power supply to demagnetize the housing; and
a controller configured to sequentially perform a plasma-processing process of plasma-processing the substrate by controlling the plasma generation unit and the electromagnet unit and a demagnetization process of demagnetizing the magnetic inductor by controlling the AC power supply.
